(19) United States
(12) Patent Application Publication
(10) Pub. No.: US 2010/0260994 A1
(43) Pub. Date: Oct. 14, 2010

(54) SUBSTRATE COATED WITH AMORPHOUS HYDROGENATED CARBON

(76) Inventors: Roland Groenen, Horebeke (BE); Val Lieberman, Oostakker (BE); Kris Van Hege, Gent (BE)

Correspondence Address: FOLEY AND LARDNER LLP;SUITE 500, 3000 K STREET NW, WASHINGTON, DC, 20007, US

(21) Appl. No.: 12/747,760

(22) PCT Filed: Dec. 16, 2008
(86) PCT No.: PCT/EP08/67612

§ 371 Date: Jun. 11, 2010

(30) Foreign Application Priority Data
Dec. 20, 2007 (EP) 07150241.3

(51) Int. Cl. B32B 7/02; B05D 5/06; C23C 4/04; C23C 16/513; B32B 9/00

(52) U.S. Cl. 428/216; 427/162; 427/569; 427/446; 428/212; 428/217

(57) ABSTRACT

The invention relates to a substrate being at least partially coated with a coating comprising at least a first layer and a second layer. The first layer and the second layer comprise amorphous hydrogenated carbon. The first layer has a first Eo4 optical band gap and the second layer has a second Eo4 optical band gap. The said second Eo4 optical band gap is smaller than said first Eo4 optical band gap. The invention further relates to a method to deposit such a coating on a substrate.

### TECHNICAL FIELD

The invention relates to a substrate coated with a coating comprising at least a first layer of a polymer-like amorphous hydrogenated carbon coating having a high optical band gap and a second layer of a diamond-like amorphous hydrogenated carbon coating having a low optical band gap.

The invention further relates to a method to manufacture such a coating.

### BACKGROUND ART

Amorphous hydrogenated carbon coatings have been demonstrated to have a wide range of electronic, optical and tribological properties. A wide variety of amorphous hydrogenated carbon coatings are known in the art ranging from strongly hydrogenated polymer-like coatings to hard diamond-like carbon coatings.

A drawback of hard carbon coatings is the poor adhesion to the substrate.

This poor adhesion is caused by the high compressive stresses present in the coating. A consequence of this poor adhesion and of the high stresses is the limited coating thickness that can be reached.

To increase the adhesion to the substrate one can dope the amorphous hydrogenated carbon coating with one or more doping elements such as a metal element (Ti, Zr, W, Si, Ta) or a non metal element (N, F, O).

Another possibility to increase the adhesion to the substrate is by using one or more intermediate layers between the substrate and the amorphous hydrogenated carbon coating.

A further possibility is to apply a coating comprising a layered structure. One example comprises a coating comprising alternating layers of a diamond-like carbon coating (DLC) and a diamond-like nanocomposite (DLN) coating as described in EP 856 592.

### DISCLOSURE OF INVENTION

It is an object of the present invention to provide a substrate being at least partially coated with an amorphous hydrogenated carbon coating avoiding the problems of the prior art.

It is another object of the present invention to provide a substrate being at least partially coated with a coating comprising at least a first layer and a second layer whereby the E₀₄ optical band gap of the second layer is smaller than the E₀₄ optical band gap of the first layer.

It is a further object of the invention to provide a substrate being at least partially coated with a coating comprising a number of layered structures, each structure comprising a first layer and a second layer.

It is a further object of the invention to provide a substrate being at least partially coated with a coating having a hardness that is changing over the thickness of the coating, as for example a coating having a higher hardness at the outside of the coating.

It is a further object of the invention to provide a substrate with a coating having an improved adhesion to the substrate.

It is a further object of the invention to provide a substrate with a coating having a high thickness.

It is a further object of the invention to provide a method to manufacture a coating comprising at least a first layer of a polymer-like amorphous hydrogenated carbon coating and a second layer of a diamond-like amorphous hydrogenated carbon coating.

According to a first aspect of the present invention a substrate being at least partially coated with a coating is provided. The coating comprises at least a first layer and a second layer. Each of the first and the second layer comprise amorphous hydrogenated carbon. The first layer has a first E₀₄ optical band gap and the second layer has a second E₀₄ optical band gap. The second E₀₄ optical band gap is smaller than the first E₀₄ optical band gap.

For the purpose of this invention the E₀₄ optical band gap is defined as the photon energy at which the optical absorption coefficient α attains a threshold value of α=10⁴ cm⁻¹.

$$α = \frac{4 π k}{λ} ,$$

The absorption coefficient is defined as

whereby k is the extinction coefficient; and
λ is the wavelength of the light in cm.

The optical constants such as the refractive index and extinction coefficient are determined by spectroscopic ellipsometry. The optical constants are determined by using the Tauc-Lorentz model derived by Jellison and Modine in Appl. Phys. Lett. 69 (1996) 371 erratum 2137.

The E₀₄ optical band gap of the first layer is preferably higher than 1.6 as for example higher than 1.8.

The E₀₄ optical band gap of the second layer is preferably lower than 1.3 as for example lower than 1.1.

Both the first and the second layer comprise amorphous hydrogenated carbon. With amorphous hydrogenated carbon coating is meant any amorphous coating comprising carbon and hydrogen. In a preferred embodiment the first and the second layer comprise an amorphous hydrogenated carbon coating consisting of carbon and hydrogen. Although both the first layer and the second layer comprise amorphous hydrogenated carbon, the first layer is different from the second layer. The first layer preferably comprises a polymer-like amorphous hydrogenated carbon coating whereas the second layer preferably comprises a diamond-like amorphous hydrogenated carbon coating.

The difference between the first layer and the second layer is for example clear by comparing the properties such as the optical, mechanical, tribological and electrical properties of the first and the second layer.

For the purpose of this invention a polymer-like amorphous hydrogenated carbon coating is defined as a layer having a high hydrogen concentration, a high contribution of CHₓ endgroups (sp¹ hybridized CH endgroups, sp² hybridized CH₂ endgroups and sp³ hybridized CH₃ endgroups) and consequently a weak network of C—C bonds. Furthermore a polymer-like amorphous hydrogenated carbon coating has a high E₀₄ optical band gap being preferably higher than 1.6 as for example higher than 1.8.

A diamond-like amorphous hydrogenated carbon coating is defined as a layer having a low hydrogen concentration, a low contribution of CHₓ endgroups (sp¹ hybridized CH endgroups, sp² hybridized CH₂ endgroups and sp³ hybridized CH₃ endgroups) and consequently a strong interconnected network of C—C bonds.

A diamond-like amorphous hydrogenated carbon coating has a low E₀₄ optical band gap being preferably lower than 1.3 as for example lower than 1.1.

The terms low hydrogen concentration, hydrogen concentration, low contribution of CHₓ endgroups, high contribution of CHₓ endgroups are explained below in more detail.

The hydrogen concentration of a polymer-like amorphous hydrogenated carbon coating is preferably higher than 30 at %, more preferably higher than 40 at % or higher than 44 at %.

The hydrogen concentration of a diamond-like amorphous hydrogenated carbon coating is preferably lower than 25 at %, more preferably lower than 20 at % as for example 16 at %.

The hardness of the first layer is preferably lower than the hardness of the second layer.

The hardness of a polymer-like amorphous hydrogenated carbon coating is preferably lower than 12 GPa, as for example GPa or 8 GPa.

The hardness of a diamond-like amorphous hydrogenated carbon coating is preferably higher than 14 GPa and more preferably higher than 15 GPa as for example 18 GPa or 20 GPa.

The difference between a polymer-like amorphous hydrogenated carbon coating and a diamond-like amorphous hydrogenated carbon coating is mainly due to a different contribution of the sp^{x} hybridized CHₓ endgroups (with x equal to 1, 2 and 3).

For a polymer-like amorphous hydrogenated carbon coating the sp^{x} hybridized CHₓ endgroups with x equal to 1, 2 and 3, i.e. the sp¹ hybridized CH endgroups, the sp² hybridized CH₂ endgroups and the sp³ hybridized CH₃ endgroups, are significantly present.

For a diamond-like amorphous hydrogenated carbon coating, the sp^{x} hybridized CHₓ endgroups with x equal to 1, 2 and 3, i.e. the sp¹ hybridized CH endgroups, the sp² hybridized CH₂ endgroups and the sp³ hybridized CH₃ endgroups, are substantially absent.

The sp^{x} hybridized CHₓ groups and more particularly the sp² hybridized CH₂ endgroups and the sp³ hybridized CH₃ endgroups serve as endgroups in the bond chain. High amounts of sp^{x} hybridized CHₓ endgroups result in soft materials.

The hardness of a diamond-like amorphous hydrogenated carbon coating is thus substantially higher than the hardness of a polymer-like amorphous hydrogenated carbon coating.

The substantial absence of the sp^{x} hybridized CHₓ endgroups of a diamond-like amorphous hydrogenated carbon coating is clear from a Fourier Transform InfraRed (FTIR) transmission spectrum. An FTIR transmission spectrum of a diamond-like amorphous hydrogenated carbon coating shows two peaks separated by a peak valley in the wavenumber range between 2800 and 3400 cm⁻¹, whereas an FTIR transmission spectrum of a polymer-like amorphous hydrogenated carbon coating shows one broad peak in the wavenumber range between 2800 and 3400 cm⁻¹.

The difference between the two FTIR transmission spectra is clear by determining the first derivative of the FTIR transmission spectra in the wavenumber range between 2800 and 3400 cm⁻¹.

The first derivative of a FTIR transmission spectrum in the wavenumber range between 2800 and 3400 cm⁻¹ of a diamond-like amorphous hydrogenated carbon coating has at least three zero axis crossings. One zero-axis crossing is corresponding with the maximum absolute intensity of the first peak in the FTIR transmission spectrum, a second zero-axis crossing is corresponding with the minimum absolute intensity of the peak valley in the FTIR transmission spectrum, a third zero-axis crossing is corresponding with the maximum absolute intensity of the second peak in the FTIR transmission spectrum.

Intersections of the first derivative of the FTIR transmission spectrum with a virtual base line are not considered to be zero-axis crossings.

On the contrary the first derivative of the FTIR transmission spectrum in the wavenumber range between 2800 and 3400 cm⁻¹ of a polymer-like amorphous hydrogenated carbon coating has only one zero-axis crossing corresponding with the maximum absolute intensity of the peak in the FTIR transmission spectrum.

Intersections of the first derivative of the FTIR transmission spectrum with a virtual base line are not considered to be zero-axis crossings.

As mentioned above, a diamond-like amorphous hydrogenated carbon coating is characterized by a substantial absence of the sp¹ hybridized CH endgroups, by a substantial absence of sp² hybridized CH₂ endgroups and by a substantial absence of the sp³ hybridized CH₃ endgroups; whereas a polymer-like amorphous hydrogenated carbon coating is characterized by a significant presence of sp¹ hybridized CH endgroups, by a significant presence of sp² hybridized CH₂ endgroups and by a significant presence of the sp³ hybridized CH₃ endgroups.

From the FTIR transmission spectra it is clear that the substantial absence/significant presence of the sp^{x} hybridized CHₓ endgroups (with x equal to 1, 2 and 3) is the result of the substantial absence/significant presence of the corresponding stretching vibrations. The substantial absence/significant presence of a specific sp^{x} hybridized CHₓ endgroup is clear by a substantial absence/significant presence of the corresponding sp^{x} CHₓ stretching vibration or vibrations in a Fourier Transform InfraRed (FTIR) transmission spectrum.

The diamond-like amorphous hydrogenated carbon coating is described in more detail with respect to the substantial absence of the sp^{x} hybridized CH endgroups. In a similar way the polymer-like amorphous hydrogenated carbon coating can be described in more detail by the significant presence of the sp^{x} hybridized CH endgroups.

The substantial absence of sp¹ hybridized CH endgroups is shown
by a substantial absence of the sp¹ CH stretching vibration at a frequency of 3300 cm⁻¹ in a FTIR transmission spectrum.

The substantial absence of sp² hybridized CH₂ endgroups is shown
by a substantial absence of the sp² CH₂ symmetric stretching vibration at a frequency of 2970-2975 cm⁻¹ in a FTIR transmission spectrum; and/or
by a substantial absence of the sp² CH₂ asymmetric stretching vibration at a frequency of 3030-3085 cm⁻¹ in a FTIR transmission spectrum.

The substantial absence of sp³ hybridized CH₃ endgroups is shown
by a substantial absence of the sp³ CH₃ asymmetric stretching vibration at a frequency of 2955-2960 cm⁻¹ in a FTIR transmission spectrum; and/or
by a substantial absence of the sp³ CH₃ symmetric stretching vibration at a frequency of 2875 cm⁻¹ in a FTIR transmission spectrum.

For the purpose of this invention, with “substantial absence” of a specific vibration is meant that the area of the absorption band related to this specific vibration is less than 10% of the total area of the absorption bands in the frequency region between 2800 and 3400 cm⁻¹. Preferably, the area of the absorption band related to the specific vibration is less than 5% or even less than 1% of the total area of the absorption bands in the frequency region between 2800 and 3400 cm⁻¹.

For example, with a substantial absence of sp¹ CH stretching vibration at a frequency of 3300 cm⁻¹ is meant that the area of the absorption band with its maximum intensity at a frequency of 3300 cm⁻¹ is less than 10% of the total area of the absorption bands in the frequency region between 2800 and 3400 cm⁻¹. Preferably, the area of the absorption band with its maximum intensity at a frequency of 3300 cm⁻¹ is less than 5% or even less than 1% of the total area of the absorption bands in the frequency region between 2800 and 3400 cm⁻¹.

With a substantial absence of sp² CH₂ symmetric stretching vibration at a frequency of 2970-2975 cm⁻¹ is meant that the area of the absorption band with its maximum intensity at a frequency of 2970-2975 cm⁻¹ is less than 10% and preferably less than 5% or even less than 1% of the total area of the absorption bands in the frequency region between 2800 and 3400 cm⁻¹.

With a substantial absence of sp² CH₂ asymmetric stretching vibration at a frequency of 3030-3085 cm⁻¹ is meant that the area of the absorption band with its maximum intensity at a frequency of 3030-3085 cm⁻¹ is less than 10% and preferably less than 5% or even less than 1% of the total area of the absorption bands in the frequency region between 2800 and 3400 cm⁻¹.

With a substantial absence of sp³ CH₃ asymmetric stretching vibration at a frequency of 2955-2960 cm⁻¹ is meant that the area of the absorption band with its maximum intensity at a frequency of 2955-2960 cm⁻¹ is less than 10% and preferably less than 5% or even less than 1% of the total area of the absorption bands in the frequency region between 2800 and 3400 cm⁻¹.

With a substantial absence of sp³ CH₃ symmetric stretching vibration at a frequency of 2875 cm⁻¹ is meant that the area of the absorption band with its maximum intensity at a frequency of 2875 cm⁻¹ is less than 10% and preferably less than 5% or even less than 1% of the total area of the absorption bands in the frequency region between 2800 and 3400 cm⁻¹.

Next to a substantial absence of the sp^{x} hybridized CHₓ endgroups (with x equal to 1, 2 and 3), a diamond-like amorphous hydrogenated carbon coating is preferably further characterized by a substantial absence of the sp² hybridized CH aromatic group.

The substantial absence of the sp² hybridized CH aromatic group is clear by a substantial absence of the sp² CH aromatic stretching vibration at a frequency of 3050-3100 cm⁻¹ in a FTIR transmission spectrum.

With a substantial absence of sp² CH aromatic stretching vibration at a frequency of 3050-3100 cm⁻¹ is meant that the area of the absorption band with its maximum intensity at a frequency of 3050-3100 cm⁻¹ is less than 10% and preferably less than 5% or even less than 1% of the total area of the absorption bands in the frequency region between 2800 and 3400 cm⁻¹.

The substantial absence of sp¹ hybridized CH endgroups, of sp² hybridized CH₂ endgroups and of sp³ hybridized CH₃ endgroups in a diamond-like amorphous hydrogenated carbon coating implies the significant presence of sp³ hybridized CH groups and/or the significant presence of sp² hybridized CH groups.

The significant presence of sp³ hybridized CH groups is shown by a significant presence of the sp³ CH stretching vibration at a frequency of 2900 (±15) cm⁻¹ in a FTIR transmission spectrum.

The significant presence of sp² hybridized CH groups is shown by a significant presence of the sp² CH olefinic stretching vibration at a frequency of 3016 cm⁻¹ in a FTIR transmission spectrum.

A diamond-like amorphous hydrogenated carbon coating has preferably a sp³ content ranging between 20 and 40 at %, and more preferably between 20 and 30 at % and has a hydrogen content preferably lower than 25 at %, more preferably lower than 20 at % as for example 16 at %.

The combination of this sp³ content and this hydrogen content differentiates the diamond-like amorphous hydrogenated carbon coating from other hydrogenated amorphous carbon coatings known in the art.

The refractive index of a diamond-like amorphous hydrogenated carbon coating is preferably higher than 2.2 as for example 2.4 or 2.5.

The thickness of the first layer ranges preferably between 5 and 5000 nm and more preferably between 10 and 1000 nm as for example 100 nm, 200 nm or 500 nm.

The thickness of the second layer is preferably ranging between 5 and 5000 nm as for example between 10 and 1000 nm as for example 100 nm, 200 nm or 500 nm.

Preferably, the first layer is located closest to the substrate and the second layer is preferably located closest to the outer surface of the coating.

Possibly, the composition of the first layer is gradually changing towards the composition of the second layer.

Alternatively, the first and the second layer form layers that are well separated from each other.

By providing a coating comprising a first layer and a second layer, a coating having a hardness that is changing from having a low hardness to a high hardness is provided.

It can be preferred that an intermediate layer, such as an adhesion promoting layer is applied on the substrate before the application of the first layer. Preferred intermediate layers comprise a titanium layer, a chromium layer or a titanium or chromium based layer.

In a preferred embodiment of the present invention, a substrate at least partially coated with a coating comprising a number of layered structures is provided. Each layered structure comprises a first layer and a second layer. Each of the first and the second layer comprise amorphous hydrogenated carbon. The first layer comprises a polymer-like amorphous hydrogenated carbon coating whereas the second layer comprises a diamond-like amorphous hydrogenated carbon coating. The first layer has an E₀₄ optical band gap that is higher than the E₀₄ optical band gap of the second layer.

Preferably, the number of layered structures of the coating is ranging between 1 and 100. More preferably, the number of layered structures is ranging between 5 and 50 as for example 10.

An advantage of a coating comprising a number of layered structures comprising a first layer and a second layer is that the internal stresses of the coating are reduced. This results in coatings having an improved adhesion to the substrates. Furthermore, this allows depositing thicker coatings without spalling off. Thicknesses of coatings that can be reached are preferably higher than 2 μm and more preferably higher than 5 μm as for example 10 μm or 25 μm.

Preferably, a first layer of a layered structure is located closer to the substrate than a second layer of a layered structure.

Possibly, the composition of the first layer of a layered structure is gradually changing towards the composition of the second layer of this layered structure.

Alternatively, the first and the second layer of a layered structure form layers that are well separated from each other.

Similarly, it is possible that the composition of the second layer of a layered structure is gradually changing towards the composition of the first layer of the subsequent layered structure.

Alternatively, the second layer of a layered structure and the first layer of the subsequent layered structure form layers that are well separated.

It can be preferred that an intermediate layer, such as an adhesion promoting layer is applied on the substrate before the application of the first layer. Preferred intermediate layers comprise a titanium layer, a chromium layer, a titanium based layer or a chromium based layer.

As substrate any substrate can be considered such as a metal substrate, a metal alloy substrate, a ceramic substrate, a glass substrate or a polymer substrate.

According to a second aspect of the present invention a method to manufacture a coating comprising at least a first layer and a second layer is provided. The method comprises the steps of
a) providing a substrate;
b) depositing a first layer comprising amorphous hydrogenated carbon on said substrate, said first layer having a first E₀₄ optical band gap;
c) depositing a second layer comprising amorphous hydrogenated carbon on said first layer, said second layer having a second E₀₄ optical band gap; whereby said second E₀₄ optical band gap being smaller than said first E₀₄ optical band gap

The first layer and the second layer can be deposited by any technique known in the art, as for example by means of ion beam deposition, plasma sputtering, laser ablation. Preferably, the first and second layer are deposited by means of chemical vapour deposition (CVD), more particularly by means of plasma enhanced chemical vapor deposition (PECVD).

Preferred methods to deposit the first and the second layer comprise the use of a remote plasma technique as for example a microwave discharge, an inductively coupled plasma or an expanding thermal plasma.

Preferably, the method comprises the use of a remote plasma characterized by a low electron temperature, typically below 0.4 eV.

Although the first layer and the second layer are different, they can be applied both by a remote plasma technique, for example by changing one or more of the process parameters such as the flow of the carrier gas and/or the flow of the carbon containing precursor gas during the deposition.

One preferred method comprises the use of an expanding thermal plasma (ETP).

The ETP deposition setup comprises one or more expanding thermal plasma sources and a low pressure deposition chamber. The ETP source preferably comprises a cascaded arc. A carrier gas (as for example argon, hydrogen, nitrogen or a mixture thereof) flows though the plasma source. This gas is ionized generating a plasma at a pressure of for example 0.5 bar. When the plasma arrives at the exit of the cascaded arc, it expands into the low pressure deposition chamber. In the deposition chamber the precursor gases necessary for the deposition are added to the plasma. The plasma mixture, which consists of the gases mentioned and the radicals, ions and electrons originating thereof, is transported subsonically towards the substrate.

The ETP deposition technique allows depositing hydrogenated amorphous carbon coatings with a high deposition rate, for example deposition rates higher than 15 nm/s or higher than 20 nm/s, for example 40 nm/s or 60 nm/s.

In a preferred method to deposit a diamond-like amorphous hydrogenated carbon the ratio of carrier gas ion flow emanating from the ETP source to the flow of introduced carbon containing precursor gas is preferably lower than 10, for example 5, 2 or 1.

Examples of carbon containing precursor gas comprise methane, ethane, ethylene, acetylene, propane, butane, benzene and toluene.

The ratio of the inert gas flow emanating from the ETP source to the flow of introduced carbon containing precursor gas has a significant influence on the properties of the hydrogenated amorphous carbon coating.

In a preferred embodiment of the present invention steps b and c are repeated a number of times. The number of times steps b and c are repeated corresponds with the number of layered structures in the deposited coating, whereby a structure comprises a first layer and a second layer. The number of layered structures ranges preferably between 1 and 100 as for example between 5 and 50.

In some embodiments, it can be preferred that the method comprises an additional step of depositing an intermediate layer, such as an adhesion promoting layer, on the substrate before the deposition of the first layer. Preferred intermediate layers comprise a titanium layer, a chromium layer, a titanium based layer or a chromium based layer.

In some embodiments the first layer of a layered structure is gradually changing towards the composition of the second layer of this layered structure.

Alternatively, the first and the second layer of a layered structure form layers that are well separated from each other.

### BRIEF DESCRIPTION OF FIGURES IN THE DRAWINGS

The invention will now be described into more detail with reference to the accompanying drawings wherein

FIG. 1 shows a substrate coated with a coating comprising a first and a second layer;

FIG. 2 shows a substrate coated with a coating comprising a number of layered structures, each structure comprising a first and a second layer;

FIG. 3 shows FTIR transmission spectra of a polymer-like amorphous hydrogenated carbon coating (FIG. 3a) and of a diamond-like amorphous hydrogenated carbon coating (FIG. 3b);

FIG. 4 is an illustration of the fitted FTIR transmission spectra of FIG. 3; and

FIG. 5 is an illustration of the first derivative of the FTIR transmission spectra of FIG. 3.

### MODE(S) FOR CARRYING OUT THE INVENTION

The invention will now be described into more detail with reference to the accompanying drawings but the invention is not limited thereto but only by the claims.

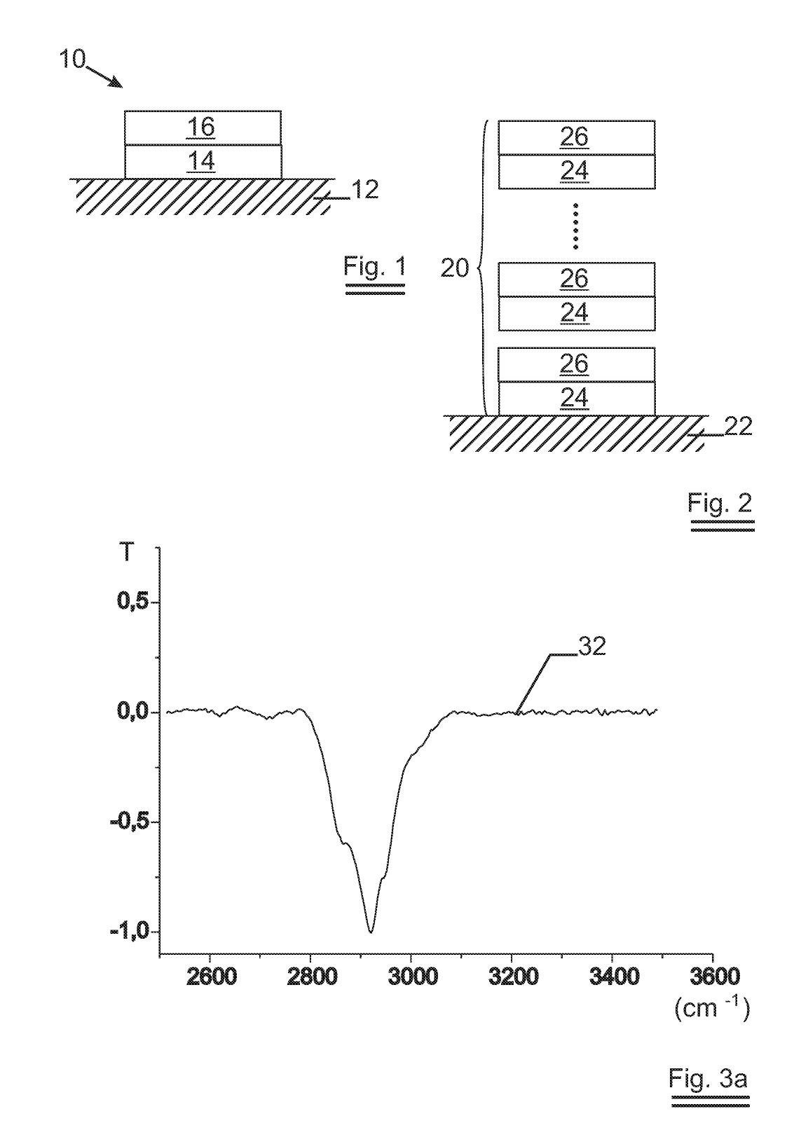

As shown in FIG. 1, a substrate 12 being at least partially coated with a coating 10 is provided. The coating comprises a first layer 14 and a second layer 16. The properties of the first layer 14 and of the second layer 16 are summarized in Table 1.

TABLE 1

| | First layer | Second layer |
|---|---|---|
| Hardness (GPa) | 7.7 | 16 |
| sp³ content | >40 | 30 |
| Hydrogen content (at %) | >30 | 22 |
| Refractive index | 2.0 | 2.5 |
| E₀₄ bandgap (eV) | 1.85 | 1.02 |

FIG. 2 shows a substrate 22 being at least partially coated with a coating 20. The coating comprises a number of layered structures. Each structure comprises a first layer 24 and a second layer 26. The first layer 24 comprises a polymer-like amorphous hydrogenated carbon coating. The second layer 26 comprises a diamond-like amorphous hydrogenated carbon coating.

Fourier Transform InfraRed (FTIR) spectroscopy is used for the qualitative characterization of the hybridization and bonding configuration of the first layer and the second layer.

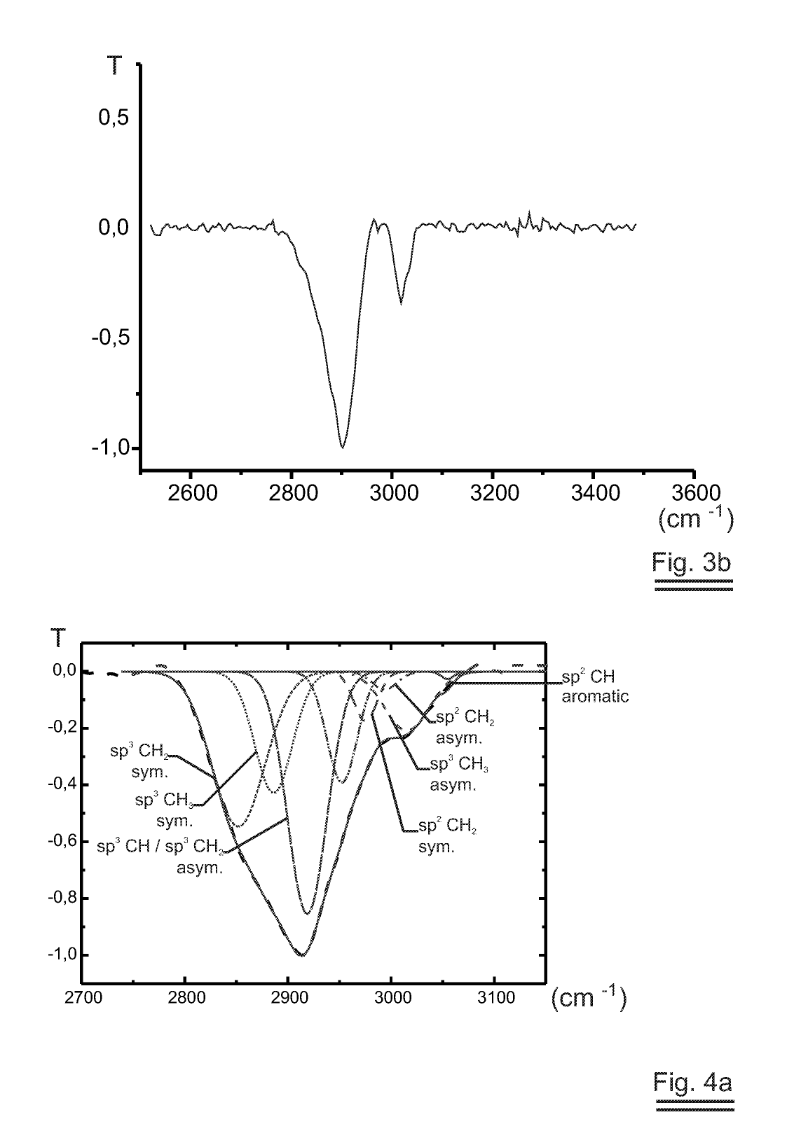

In FIG. 3 the spectra obtained by FTIR spectrosopy of a polymer-like amorphous hydrogenated carbon coating (the first layer) and of a diamond-like amorphous hydrogenated carbon coating (the second layer) are visualized. The FTIR transmission spectrum of a polymer-like amorphous hydrogenated carbon coating is given by spectrum 32 in FIG. 3a. The FTIR transmission spectrum of a diamond-like amorphous hydrogenated coating is given by spectrum 34 in FIG. 3b. In the X-axis the wavenumbers are given, the Y-axis shows the transmission.

The spectrum of the first layer is clearly different from the spectrum of the second layer. The FTIR spectrum of the first layer shows one broad peak, whereas the FTIR spectrum of the second layer shows two peaks separated by a valley.

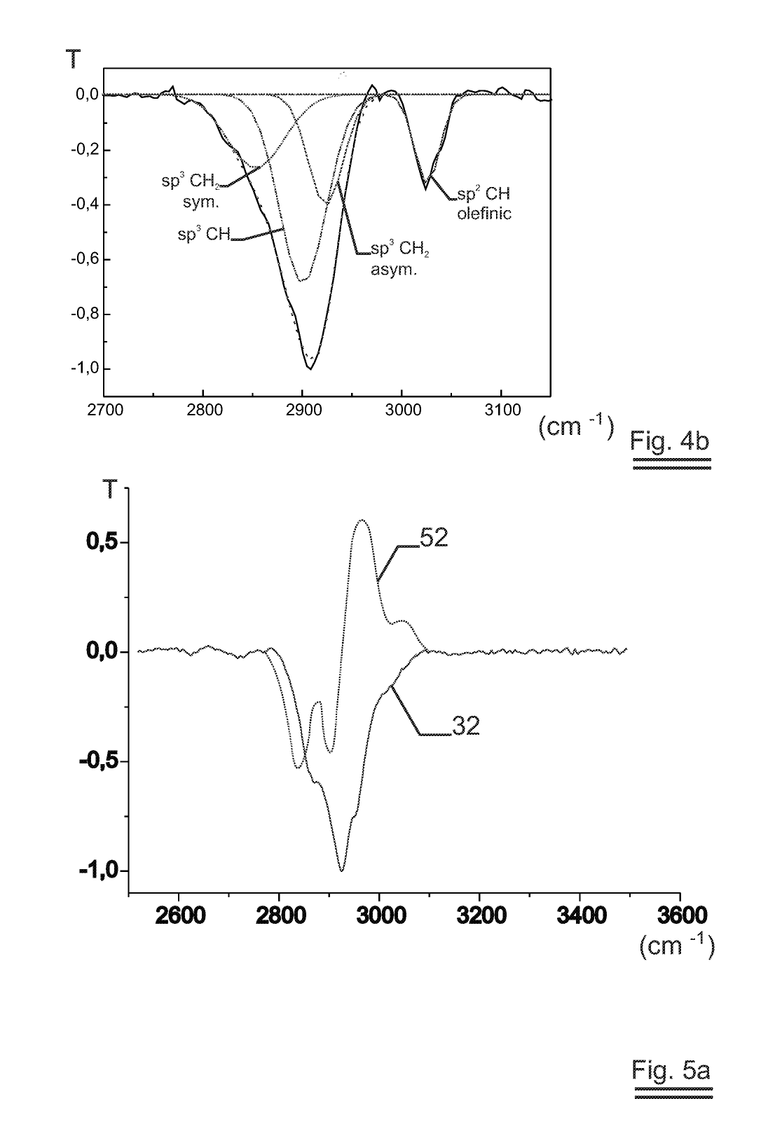

The FTIR transmission spectra of the first layer and the second layer have been fitted in the wavenumber range from 2800 cm⁻¹ to 3400 cm⁻¹. The fitted FTIR transmission spectrum of the first layer is given in FIG. 4a. The fitted FTIR transmission spectrum corresponds with the spectrum given in J. Appl. Phys., Vol. 80, p. 5986, 1996. The fitted FTIR transmission spectrum of the second layer is given in FIG. 4b.

To obtain the fitted FTIR transmission spectrum, first the interference background is determined by measuring the FTIR transmission spectrum of a blank sample. After the subtraction of the interference background, the individual absorption peaks representing the specific stretching vibrations are determined. In the fit procedure each absorption peak is represented by a Gaussian function. For the fit procedure the peak positions are kept fixed. The parameters that vary are thus the peak height and the peak width.

The stretching vibrations and corresponding bonding types used are given in Table 2. These vibrations correspond with vibrations given in J. Appl. Phys., Vol. 84, No. 7, p. 3836-3847, 1998, Table I and Table II and in Solid State Comm., Vol. 48, No. 2, p. 105-108, 1983, Table II.

TABLE 2

| Stretching vibration | | |
|---|---|---|
| [cm⁻¹] | | Bonding type |
| 2850 | cm⁻¹ | sp³ CH₂ symmetric stretching |
| 2875 | cm⁻¹ | sp³ CH₃ symmetric stretching |
| 2900 | cm⁻¹ | sp³ CH stretching |
| 2924 | cm⁻¹ | sp³ CH₂ asymmetric stretching |
| 2955-2960 | cm⁻¹ | sp³ CH₃ asymmetric stretching |
| 2970-2975 | cm⁻¹ | sp² CH₂ symmetric stretching |
| 3016 | cm⁻¹ | sp² CH olefinic stretching |
| 3030-3085 | cm⁻¹ | sp² CH₂ asymmetric stretching |
| 3050-3100 | cm⁻¹ | sp² CH aromatic stretching |
| 3300 | cm⁻¹ | sp¹ CH stretching |

From FIG. 3 and FIG. 4 it is clear that the FTIR transmission spectrum of the first layer in the wavenumber region between 2800 cm⁻¹ and 3400 cm⁻¹ is different from the FTIR transmission spectrum of the second layer. This difference is due to the substantial absence of sp¹ hybridized CH endgroups, to the substantial absence of sp² hybridized CH₂ endgroups and to the substantial absence of spa hybridized CH₃ endgroups in the second layer.

The substantial absence of sp¹ hybridized CH endgroups is shown by a substantial absence of the sp¹ CH stretching vibration at a frequency of 3300 cm⁻¹.

The substantial absence of sp² hybridized CH₂ endgroups is shown by a substantial absence of the sp² CH₂ symmetric stretching vibration at a frequency of 2970-2975 cm⁻¹, and/or by a substantial absence of the sp² CH₂ asymmetric stretching vibration at a frequency of 3030-3085 cm⁻¹ in a FTIR transmission spectrum.

The substantial absence of sp³ hybridized CH₃ endgroups is shown by a substantial absence of the sp³ CH₃ asymmetric stretching vibration at a frequency of 2955-2960 cm⁻¹ and/or by a substantial absence of the sp³ CH₃ symmetric stretching vibration at a frequency of 2875 cm⁻¹ in a FTIR transmission spectrum.

Furthermore, the second layer is characterized by the presence of sp³ hybridized CH groups and/or by the presence of sp² hybridized CH groups shown by the presence of the sp³ CH stretching vibration at a frequency of 2900 (±15) cm⁻¹ in a FTIR transmission spectrum and/or by the presence of the sp² CH olefinic stretching vibration at a frequency of 3016 cm⁻¹ in a FTIR transmission spectrum.

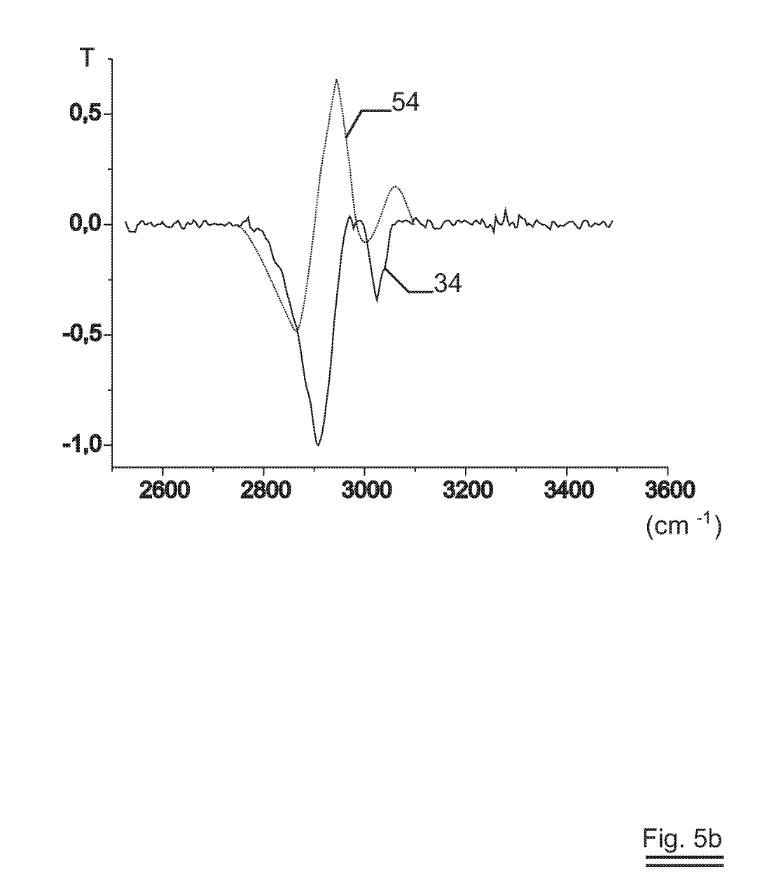

FIG. 5 shows the first derivative of the FTIR transmission spectra given in FIG. 3. The first derivative of the FTIR transmission spectrum of a polymer-like hydrogenated carbon coating is given by spectrum 52 in FIG. 5a. The first derivative of the FTIR transmission spectrum of a diamond-like hydrogenated carbon coating is given by spectrum 54 in FIG. 5b. In the X-axis the wavenumbers are given, the Y-axis shows the transmission.

Spectrum 52 of FIG. 5a has one zero-crossing in the wavenumber range between 2800 and 3400 cm⁻¹, whereas spectrum 54 of FIG. 5b has three zero crossings in the wavenumber range between 2800 and 3400 cm⁻¹. Intersections of the first derivative of the FTIR transmission spectrum with a virtual base line are not considered to be zero-axis crossings.

The first derivative of a FTIR transmission spectrum in the wavenumber range between 2800 and 3400 cm⁻¹ of a diamond-like amorphous hydrogenated carbon coating (spectrum 54) has three zero axis crossings. One zero-axis crossing is corresponding with the maximum absolute intensity of the first peak in the FTIR transmission spectrum, a second zero-axis crossing is corresponding with the minimum absolute intensity of the peak valley in the FTIR transmission spectrum, a third zero-axis crossing is corresponding with the maximum absolute intensity of the second peak in the FTIR transmission spectrum.

On the contrary the first derivative of the FTIR transmission spectrum in the wavenumber range between 2800 and 3400 cm⁻¹ of a polymer-like amorphous hydrogenated carbon coating (spectrum 52) has only one zero-axis crossing corresponding with the maximum absolute intensity of the peak in the FTIR transmission spectrum.

1. A substrate being at least partially coated with a coating, said coating comprising at least a first layer and a second layer, said first layer and said second layer comprising amorphous hydrogenated carbon; said first layer having a first E₀₄ optical band gap and said second layer having a second E₀₄ optical band gap, said second E₀₄ optical band gap being smaller than said first E₀₄ optical band gap.

2. A substrate according to claim 1, whereby said first layer comprises a polymer-like amorphous hydrogenated carbon coating and said second layer comprises a diamond like amorphous hydrogenated carbon coating.

3. A substrate according to claim 1, whereby said first layer has an E₀₄ optical band gap of at least 1.6.

4. A substrate according to claim 1, whereby said second layer has an E₀₄ optical band gap lower than 1.3.

5. A substrate according to claim 1, whereby the sp^{x} hybridized CHₓ endgroups (with x equal to 1, 2 and 3) in said second layer are substantially absent.

6. A substrate according to claim 1, whereby said first layer has a hydrogen concentration higher than 30 at % and said second layer has a hydrogen concentration lower than 25 at %.

7. A substrate according to claim 1, whereby the hardness of said first layer is lower than the hardness of said second layer.

8. A substrate according to claim 1, whereby said first layer has a hardness lower than 12 GPa and said second layer has a hardness higher than 14 GPa.

9. A substrate according to claim 1, whereby said first layer and said second layer have a thickness ranging between 5 and 5000 nm.

10. A substrate according to claim 1, whereby said first layer is located closer to said substrate and said second layer is located closer to the outer surface of said coating.

11. A substrate according to claim 1, whereby said coating comprises a number of layered structures, each structure comprising a first layer and a second layer; said number of layered structures ranges between 1 and 100.

12. A substrate according to claim 1, whereby the composition of said first layer is gradually changing towards the composition of said second layer.

13. A substrate according to claim 1, whereby said first and said second layer form two layers separated from each other.

14. A substrate according to claim 1, whereby an intermediate layer such as an adhesion promoting layer is applied on the substrate before the application of the first layer.

15. A substrate according to claim 14, whereby said intermediate layer comprises a titanium layer, a chromium layer, a titanium based layer or a chromium based layer.

16. A method to deposit a coating on a substrate, said method comprising the steps of:
providing a substrate;
depositing a first layer on said substrate, said first layer having a first E₀₄ optical band gap;
depositing a second layer on said first layer, said second layer having a second E₀₄ optical band gap; whereby said second E₀₄ optical band gap being smaller than said first E₀₄ optical band gap.

17. A method according to claim 16, whereby said first layer comprises a polymer-like amorphous hydrogenated carbon coating and said second layer comprises a diamond like amorphous hydrogenated carbon coating.

18. A method according to claim 16, whereby said first layer has an E₀₄ optical band gap of at least 1.6.

19. A method according to claim 16, whereby said second layer has an E₀₄ optical band gap lower than 1.3.

20. A method according to claim 16, whereby said first layer and/or said second layer are applied by a remote plasma technique.

21. A method according to claim 20, whereby said remote plasma has an electron temperature lower than 0.4 eV.

22. A method according to claim 20, whereby said remote plasma comprises an expanding thermal plasma.

23. A method according to claim 16, whereby the depositing steps are repeated a number of times, whereby said number ranges between 1 and 100.
